(19) United States
(12) Patent Application Publication
(10) Pub. No.: US 2026/0093879 A1
(43) Pub. Date: Apr. 2, 2026

(54) DESIGN SUPPORT DEVICE, DESIGN SUPPORT SYSTEM, DESIGN SUPPORT PROGRAM, AND DESIGN SUPPORT METHOD

(71) Applicant: KABUSHIKI KAISHA TOSHIBA, Tokyo (JP)

(72) Inventors: Hiro GANGI, Marugame Kagawa (JP); Yasunori TAGUCHI, Kawasaki Kanagawa (JP); Kouta NAKATA, Chigasaki Kanagawa (JP); Yusuke KOBAYASHI, Yokohama Kanagawa (JP); Tomoaki INOKUCHI, Yokohama Kanagawa (JP); Taichi FUKUDA, Yokohama Kanagawa (JP)

(73) Assignee: KABUSHIKI KAISHA TOSHIBA, Tokyo (JP)

(21) Appl. No.: 19/243,843

(22) Filed: Jun. 20, 2025

(30) Foreign Application Priority Data
Oct. 2, 2024 (JP) 2024-173368

(51) Int. Cl. G06F 30/30

(52) U.S. Cl. CPC G06F 30/30

(57) ABSTRACT

According to one embodiment, a design support device includes an interface and a processing circuit. The interface acquires image data related to a target device, and correspondence information. One of the correspondence information corresponds to one of the image data. The one of the correspondence information includes a design value, a score, and a characteristic value related to the one of the image data. The processing circuit includes a data generator to perform a first operation. In the first operation, the data generator generates first display data for displaying an output image including a plurality of symbols. One of the symbols corresponds to one of feature values. One of the feature values corresponds to the one of the image data. The symbols are displayed in a first display format according to the correspondence information corresponding to the image data.

### CROSS-REFERENCE TO RELATED APPLICATIONS

This application is based upon and claims the benefit of priority from Japanese Patent Application No. 2024-173368, filed on Oct. 2, 2024; the entire contents of which are incorporated herein by reference.

### FIELD

Embodiments described herein relate generally to a design support device, a design support system, a design support program, and a design support method.

### BACKGROUND

For example, various device products such as semiconductor devices are designed. A design support device that efficiently supports the design is desired.

### BRIEF DESCRIPTION OF THE DRAWINGS

FIG. 1 is a schematic diagram illustrating a design support device according to a first embodiment;

FIG. 2 is a schematic diagram illustrating the design support device according to the first embodiment;

FIG. 3 is a schematic diagram illustrating the design support device according to the first embodiment;

FIG. 4 is a schematic diagram illustrating the design support device according to the first embodiment;

FIG. 5 is a schematic diagram illustrating the design support device according to the first embodiment;

FIG. 6 is a schematic diagram illustrating a design support device according to the first embodiment; and

FIG. 7 is a flowchart illustrating a design support method according to a fourth embodiment.

### DETAILED DESCRIPTION

According to one embodiment, a design support device includes an interface and a processing circuit. The interface is configured to acquire a plurality of image data related to a target device, and a plurality of correspondence information. One of the plurality of correspondence information corresponds to one of the plurality of image data. The one of the plurality of correspondence information includes a design value related to the one of the plurality of image data, a score related to the one of the plurality of image data, and a characteristic value related to the one of the plurality of image data. The processing circuit includes a data generator configured to perform a first operation. In the first operation, the data generator is configured to generate first display data for displaying an output image including a plurality of symbols. One of the plurality of symbols corresponds to one of a plurality of feature values. One of the plurality of feature values corresponds to the one of the plurality of image data. The plurality of symbols are displayed in a first display format according to the plurality of correspondence information corresponding to the plurality of image data.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

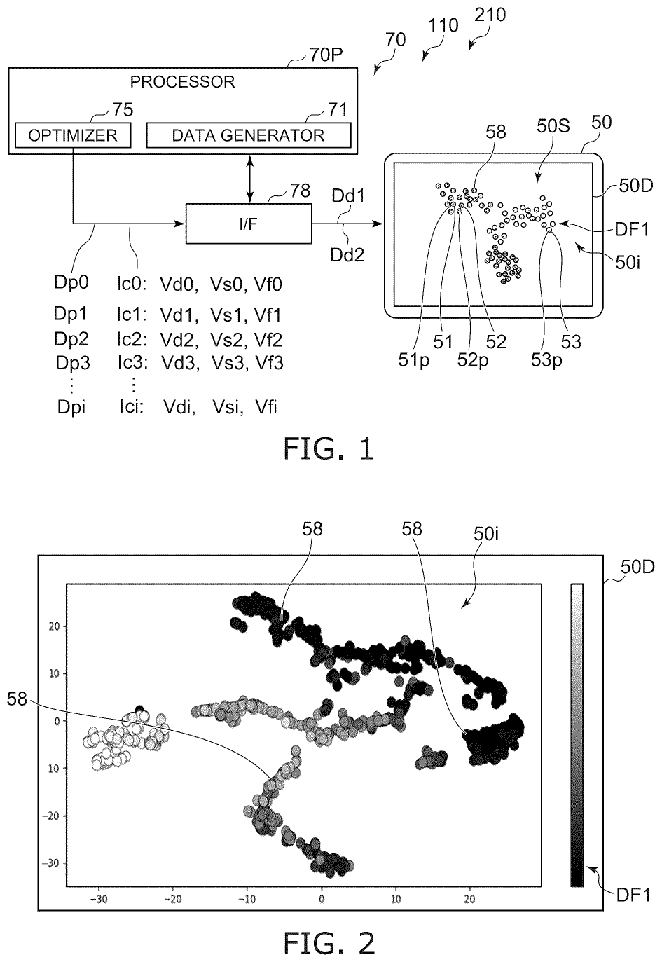

FIG. 1 is a schematic diagram illustrating a design support device according to the first embodiment.

As shown in FIG. 1, a design support device 110 according to the embodiment includes an interface 78 and a processing circuit 70.

The interface 78 is configured to acquire a plurality of image data Dp0 and a plurality of correspondence information Ic0. The plurality of image data Dp0 include image data related to a target device.

The target device may be any target product to which the design support device 110 according to the embodiment is applied. The target device may include, for example, at least one of a semiconductor device, a magnetic device, a MEMS device, a sensor device, an imaging device, or a light emitting device. Examples of target devices are described later.

One of the plurality of correspondence information Ic0 corresponds to one of the plurality of image data Dp0. The plurality of correspondence information Ic0 each correspond to one of the plurality of image data Dp0.

One of the plurality of correspondence information Ic0 includes a design value Vd0 for one of the plurality of image data Dp0, a score Vs0 for one of the plurality of image data Dp0, and a characteristic value Vf0 for one of the plurality of image data Dp0. The score Vs0 may correspond to an objective function, for example.

For example, the plurality of image data Dp0 include first image data Dp1, second image data Dp2, and third image data Dp3. For example, the plurality of correspondence information Ic0 include first correspondence information Ic1, second correspondence information Ic2, and third correspondence information Ic3. The first correspondence information Ic1 corresponds to the first image data Dp1. The second correspondence information Ic2 corresponds to the second image data Dp2. The third correspondence information Ic3 corresponds to the third image data Dp3.

The first correspondence information Ic1 includes a first design value Vd1 related to the first image data Dp1, a first score Vs1 related to the first image data Dp1, and a first characteristic value Vf1 related to the first image data Dp1. The second correspondence information Ic2 includes a second design value Vd2 related to the second image data Dp2, a second score Vs2 related to the second image data Dp2, and a second characteristic value Vf2 related to the second image data Dp2. The third correspondence information Ic3 includes a third design value Vd3 related to the third image data Dp3, a third score Vs3 related to the third image data Dp3, and a third characteristic value Vf3 related to the third image data Dp3.

For example, the plurality of image data Dp0 include an ith image data Dpi, where “i” is an integer equal to or greater than 2. For example, the plurality of correspondence information Ic0 include the ith correspondence information Ici. The ith correspondence information Ici corresponds to the ith image data Dpi. The ith correspondence information Ici includes an ith design value Vdi related to the ith image data Dpi, an ith score Vsi related to the ith image data Dpi, and an ith characteristic value Vfi related to the ith image data Dpi.

The processing circuit 70 includes a data generator 71. The data generator 71 is configured to perform a first operation. The processing circuit 70 may include, for example, an electronic circuit. The processing circuit 70 may include, for example, a CPU (Central Processing Unit). The data generator 71 may include, for example, an electronic circuit.

In the first operation, the data generator 71 is configured to generate first display data Dd1. The first display data Dd1 may be supplied to a display device 50, for example. An output image 50i based on the first display data Dd1 is displayed in a display area 50D of the display device 50.

The output image 50i includes a plurality of symbols 58. The plurality of symbols 58 correspond to the respective feature values of the plurality of image data Dp0. One of the plurality of symbols 58 corresponds to one of the plurality of feature values. One of the plurality of feature values corresponds to one of the plurality of image data Dp0. The plurality of symbols 58 are displayed in a first display format DF1 according to the plurality of correspondence information Ic0 corresponding to the plurality of image data Dp0, respectively.

The first display format DF1 may include, for example, color. The plurality of symbols 58 are displayed in different colors according to the plurality of correspondence information Ic0. The plurality of symbols 58 may be, for example, marks having a specific shape. In the example of FIG. 1, the plurality of symbols 58 are circular marks. The plurality of symbols 58 are displayed in colors according to the correspondence information Ic0 corresponding to the plurality of symbols 58.

For example, plurality of image data Dp0 with different designs are generated for the target device. Each of the plurality of image data Dp0 has different characteristics according to the different designs. The different characteristics are reflected in the image data Dp0. In one example, when the target product is a semiconductor device, a simulation is performed for characteristics such as a current density distribution in the semiconductor device. Image data Dp0 representing the result is generated. The plurality of image data Dp0 reflect different characteristics (performance, for example).

For example, the plurality of feature values are calculated for the plurality of image data Dp0. The plurality of feature values correspond to different characteristics (performance) of the target product. In the embodiment, plurality of symbols 58 corresponding to the plurality of feature values of the plurality of image data Dp0 for the target product are displayed in the first display format DF1 (for example, different colors) according to the plurality of correspondence information Ic0 corresponding to each of the plurality of image data Dp0. Thereby, the user of the design support device 110 easily recognizes the different characteristics (performance) of the target product. According to the embodiment, a design support device that can provide efficient support can be provided. For example, an efficient GUI (Graphical User Interface) can be provided.

For example, the plurality of symbols 58 are located at positions in the display space 50S according to the respective feature values of the plurality of image data Dp0. The display space 50S may be, for example, two-dimensional. An easy-to-view display is provided.

For example, as already explained, the plurality of image data Dp0 include the first image data Dp1, the second image data Dp2, and the third image data Dp3, etc. The first image data Dp1 has a first feature value. The second image data Dp2 has a second feature value. The third image data Dp3 has a third feature value.

The plurality of symbols 58 include a first symbol 51 corresponding to the first feature value, a second symbol 52 corresponding to the second feature value, and a third symbol 53 corresponding to the third feature value (see FIG. 1). The first symbol 51 is located at a first display position 51p in the display space 50S. The second symbol 52 is located at a second display position 52p in the display space 50S. The third symbol 53 is located at a third display position 53p in the display space 50S.

For example, in a case where a first absolute value of a first difference between the first feature value and the second feature value is smaller than a second absolute value of a second difference between the first feature value and the third feature value, a first distance between the first display position 51p and the second display position 52p in the display space 50S is shorter than a second distance between the first display position 51p and the third display position 53p.

For example, plurality of symbols 58 relating to the plurality of image data Dp0 having similar feature values are located close to each other in the display space 50S. Plurality of symbols 58 relating to plurality of image data Dp0 having different feature values are located far apart in the display space 50S. By the first display data Dd1 that displays such an output image 50i, the user can efficiently recognize, for example, the differences in feature values. The design support device 110 allows the user to efficiently recognize the features of the plurality of image data Dp0.

For example, the output image 50i includes a two-dimensional scatter plot of plurality of symbols 58. For example, the data generator 71 is configured to perform dimensionality compression of plurality of feature values Fv0 (plurality of feature value vectors). The dimensionality compression includes performing at least one of t-SNE (t-Distributed Stochastic Neighbor Embedding), PCA (Principal component analysis), or MDS (Multi-dimensional scaling).

In the embodiment, the feature values relating to the plurality of image data Dp0 are represented by plurality of symbols 58 at positions in the display space 50S. Furthermore, the plurality of symbols 58 are displayed in the first display format DF1 (e.g., color, etc.) according to the plurality of correspondence information Ic0. By displaying with the positions in the display space 50S and with the first display format DF1 (e.g., color, etc.), the relationship between the characteristics (performance, etc.) of the target device and the correspondence information Ic0 (design value Vd0, score Vs0, and characteristic value Vf0) can be efficiently recognized.

The first display format DF1 may include a display format based on at least one of the colors of the plurality of symbols 58 according to the plurality of correspondence information Ic0, the brightness of the plurality of symbols 58 according to the plurality of correspondence information Ic0, the size of the plurality of symbols 58 according to the plurality of correspondence information Ic0, or the temporal change of the plurality of symbols 58 according to the plurality of correspondence information Ic0. The temporal change of the plurality of symbols 58 may include, for example, blinking and the blinking period.

FIG. 2 is a schematic diagram illustrating the design support device according to the first embodiment.

FIG. 2 illustrates an output image 50i based on the first display data Dd1. In this example, the plurality of symbols 58 are circular marks. The plurality of symbols 58 are displayed in the first display format DF1 according to the plurality of correspondence information Ic0. For example, the circular marks are displayed in different colors or different brightnesses (intensities). A user of the design support device 110 can efficiently recognize the differences in the feature values Fv0 of the plurality of image data Dp0 from their positions in the output image 50i and the first display format DF1. Design can be efficiently supported.

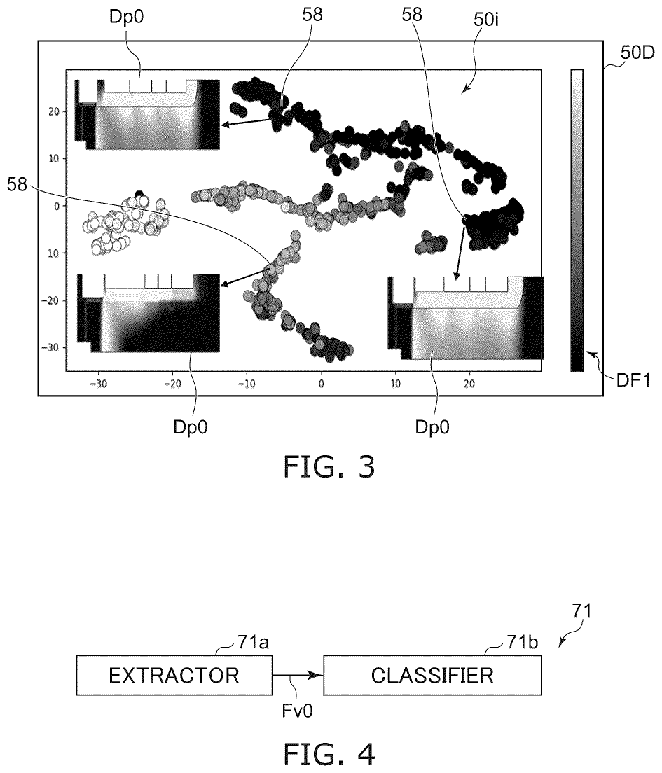

FIG. 3 is a schematic diagram illustrating the design support device according to the first embodiment.

As shown in FIG. 3, at least one of plurality of image data Dp0 may be displayed in the output image 50i based on the first display data Dd1.

In this way, the data generator 71 may be configured to further perform an image display operation. In the image display operation, the data generator 71 may be configured to display at least one of the plurality of image data Dp0 together with at least a part of the plurality of symbols 58. In this example, the target device is a transistor (semiconductor device). The plurality of image data Dp0 indicate the electric field strength distribution in the transistor.

FIG. 4 is a schematic diagram illustrating the design support device according to the first embodiment.

As shown in FIG. 4, the data generator 71 may include a feature extractor 71a. The feature extractor 71a extracts the feature value Fv0 from the plurality of image data Dp0. The dimension of the feature value Fv0 is lower than the dimension of the plurality of image data Dp0.

In one example, the dimension of one of the plurality of image data Dp0 is 1024×512×3. The feature extractor 71a extracts the feature value Fv0 (e.g., a feature vector) in a low-dimension from the plurality of image data Dp0, for example, by a method such as IDFD (Instance Discrimination and Feature Decorrelation). The dimension of the feature value Fv0 is lower than the dimension of one of the plurality of image data Dp0. The dimension of the feature value Fv0 may be, for example, 100 dimensions or more.

For example, expression learning may be performed in the feature extractor 71a. Based on the expression learning, the plurality of feature values Fv0 may be extracted.

As shown in FIG. 4, the data generator 71 may include an image classifier 71b. For example, the plurality of feature values Fv0 may be supplied from the feature extractor 71a to the image classifier 71b. The image classifier 71b is configured to classify the plurality of image data Dp0 based on the plurality of feature values Fv0.

For example, the image classifier 71b clusters the plurality of image data Dp0 using the plurality of feature values Fv0. In the clustering, for example, k-means may be applied. In one example, the numbers of the plurality of classifications (cluster numbers) may be determined based on at least a part of the plurality of correspondence information Ic0. The numbers of the plurality of classifications (cluster numbers) may be determined based on the objective function (score Vs0), for example. The number for one of the plurality of classifications may be determined based on the median value of the objective function included in that classification, for example.

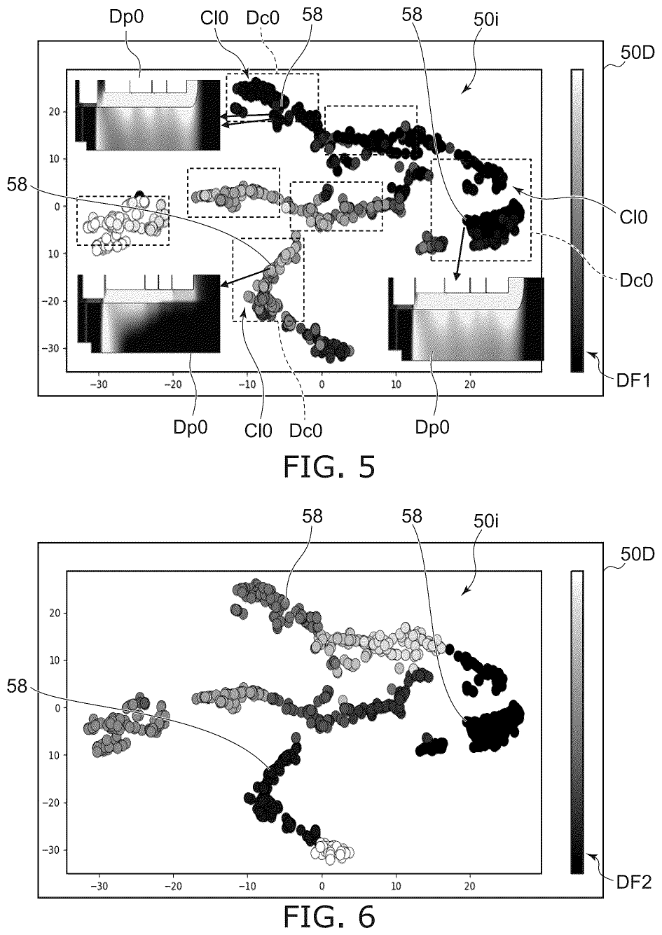

FIG. 5 is a schematic diagram illustrating the design support device according to the first embodiment.

As shown in FIG. 5, the output image 50i may include a cluster display Dc0. The cluster display Dc0 corresponds to the plurality of clusters Cl0. The plurality of clusters Cl0 are obtained, for example, by classifying the plurality of image data Dp0 based on the plurality of feature values Fv0. By displaying the cluster display Dc0, the design support device 110 can enable the user to more efficiently recognize the characteristics of the plurality of image data Dp0.

At least a part of the first display format DF1 may correspond to plurality of clusters Cl0.

The shape of the cluster display Dc0 in the output image 50i may be a polygon, a circle, or a flattened circle, etc. The shape of the cluster display Dc0 in the output image 50i may be arbitral.

For example, the cluster display Dc0 in the output image 50i may overlap a part of the plurality of symbols 58 corresponding to that cluster display Dc0. A part of the plurality of symbols 58 corresponding to the cluster display Dc0 may exist inside the cluster display Dc0 in the output image 50i. For example, the cluster display Dc0 in the output image 50i may overlap 90% or more of the plurality of symbols 58 corresponding to that cluster display Dc0.

FIG. 6 is a schematic diagram illustrating a design support device according to the first embodiment.

As shown in FIG. 6, in the design support device 110 according to the embodiment, the data generator 71 may be configured to perform a second operation. The plurality of symbols 58 are displayed in a second display format DF2 corresponding to the plurality of clusters Cl0.

That is, in the second operation, the data generator 71 is configured to generate second display data Dd2 (see FIG. 1) that displays the output image 50i including the plurality of symbols 58. One of the plurality of symbols 58 corresponds to one of the plurality of feature values Fv0. One of the plurality of feature values Fv0 corresponds to one of the plurality of image data Dp0. In the second operation, the plurality of symbols 58 are displayed in the second display format DF2 corresponding to the plurality of clusters Cl0 into which the plurality of image data Dp0 are classified based on the plurality of feature values Fv0. The design support device 110 can allow the user to recognize the characteristics of the plurality of image data Dp0 more efficiently. Support is provided efficiently.

The first operation may be omitted and the second operation may be performed. In this case, the design support device 110 includes the interface 78 and the processing circuit 70. The interface 78 is configured to acquire the plurality of image data Dp0 related to the target device and the plurality of correspondence information Ic0. As already explained, one of the plurality of correspondence information Ic0 corresponds to one of the plurality of image data Dp0. One of the plurality of correspondence information Ic0 includes the design value Vd0 related to one of the plurality of image data Dp0, the score Vs0 related to one of the plurality of image data Dp0, and the characteristic value Vf0 related to one of the plurality of image data Dp0.

The processing circuit 70 includes the data generator 71 configured to perform the second operation. In the second operation, the data generator 71 is configured to generate the second display data Dd2 (see FIG. 1) that displays the output image 50i including the plurality of symbols 58. One of the plurality of symbols 58 corresponds to one of the plurality of feature values Fv0. One of the plurality of feature values Fv0 corresponds to one of the plurality of image data Dp0. The plurality of symbols 58 are displayed in the second display format DF2 according to the plurality of clusters Cl0 into which the plurality of image data Dp0 are classified based on the plurality of feature values Fv0.

The second display format DF2 may include a display format based on at least one of the colors of the symbols 58 corresponding to the clusters Cl0, the brightness of the symbols 58 corresponding to the clusters Cl0, the size of the symbols 58 corresponding to the clusters Cl0, or the temporal change of the symbols 58 corresponding to the clusters Cl0. The temporal change of the symbols 58 may include, for example, blinking and the period of the blinking.

In at least one of the first operation or the second operation, a part of the plurality of image data Dp0 may be subject to the above processing. For example, the data generator 71 may be configured to select at least one of the plurality of image data Dp0 that is not subject to the output image 50i, based on plurality of correspondence information Ic0 corresponding to each of the plurality of image data Dp0. Depending on the situation, processing (and display) related to some of the image data Dp0 may not be performed. Efficient support can be provided.

As shown in FIG. 1, the processing circuit 70 may further include an optimizer 75. The optimizer 75 is configured to derive the plurality of image data Dp0 being above-mentioned and the plurality of correspondence information Ic0 being above-mentioned. The plurality of image data Dp0 and the plurality of correspondence information Ic0 derived by the optimizer 75 are supplied to the interface 78.

The optimizer 75, for example, changes design values for the target device and calculates the characteristics of the target device. As a result, the optimizer 75 derives the plurality of image data Dp0. The optimizer 75 derives the score Vs0 (e.g., the objective function) related to each of the plurality of image data Dp0, and the characteristic value Vf0 related to each of the plurality of image data Dp0. The optimizer 75 outputs the design value Vd0, the score Vs0, and the characteristic value Vf0 along with the plurality of image data Dp0.

The location where the optimizer 75 is provided may be different from the location where the data generator 71 is provided. The circuit that operates as the optimizer 75 may be different from the circuit that operates as the data generator 71. Data transmission and reception between the optimizer 75 and the data generator 71 may be performed at least either by wire or wirelessly.

In the example of FIG. 5, at least one of the plurality of image data Dp0 corresponding to the cluster display Dc0 may be displayed. One of the plurality of image data Dp0 corresponding to one of the plurality of clusters Cl0 may be displayed. One of the plurality of image data Dp0 may be, for example, a representative image.

The representative image may correspond to, for example, image data Dp0 whose characteristic value is the median, maximum, or minimum value among the plurality of image data Dp0 corresponding to one of the plurality of clusters Cl0. The representative image may be, for example, image data Dp0 corresponding to one of the plurality of symbols 58 in one of the plurality of clusters Cl0 that is closest to the center of gravity in the output image 50i.

The representative image may correspond to, for example, image data Dp0 whose design value is the median, maximum value, or minimum value among plurality of image data Dp0 corresponding to one of plurality of clusters Cl0.

The representative image may correspond to, for example, image data Dp0 whose score Vs0 is the median, maximum, or minimum value among the plurality of image data Dp0 corresponding to one of the plurality of clusters Cl0. The representative image may be, for example, image data Dp0 corresponding to one of the plurality of symbols 58 that is closest to the center of gravity in the output image 50i of one of the plurality of clusters Cl0.

In the example of FIG. 5, data input by the user (for example, text data, etc.) may be displayed corresponding to the cluster display Dc0. The data input by the user may include figures, etc.

The target device to which the design support device 110 according to the embodiment is applied may include, for example, a semiconductor device. In this case, at least one of the design value Vd0, the score Vs0, or the characteristic value Vf0 may include at least one selected from the group consisting of electron current density, hole current density, acceptor density, donor density, doping density, Auger recombination rate, electric field strength, horizontal component of electric field, vertical component of electric field, electrostatic potential, impact ionization coefficient, trap density, trap occupancy, lattice temperature, pseudo-Fermi potential, electron pseudo-Fermi potential, hole pseudo-Fermi potential, slope of electron pseudo-Fermi potential, slope of hole pseudo-Fermi potential, space charge density, stress, electron density, hole density, electron mobility, hole mobility, and Shockley-Read-Hall recombination rate.

In the embodiment, the target device may include at least one selected from the group consisting of, for example, semiconductor devices, magnetic devices, MEMS devices, sensor devices, imaging devices, light emitting devices, antenna devices, communication devices, computing devices, memory devices, lighting devices, motors, generators, electrical devices, manufacturing equipment, mechanical devices, robots, automobiles, aircraft, drones, ships, and tools. The manufacturing equipment may include, for example, semiconductor manufacturing equipment. At least one of the semiconductor devices and the electrical devices may include at least one of a power conversion device and a control device. The manufacturing equipment may include at least one of a gas device and abatement equipment. The mechanical device may include, for example, a crane, etc. The tool may include, for example, a screw, etc.

### Second Embodiment

The second embodiment relates to a design support system. The processing in the design support device 110 according to the embodiment may be performed by a plurality of processing circuits 70. A design support system 210 according to the embodiment (see FIG. 1) may have a configuration similar to that of the design support device 110 described above. The design support system 210 may be configured to perform at least a part of the operations described with respect to the design support device 110. The configuration described with respect to the design support device 110 can be applied to the design support system 210.

### Third Embodiment

The third embodiment relates to a design support program. The design support program causes a computer to perform a processing operation. The processing operation includes acquiring a plurality of image data Dp0 related to a target device and a plurality of correspondence information Ic0. One of the plurality of correspondence information Ic0 corresponds to one of the plurality of image data Dp0. One of the plurality of correspondence information Ic0 includes a design value Vd0 related to one of the plurality of image data Dp0, a score Vs0 related to one of the plurality of image data Dp0, and a characteristic value Vf0 related to one of the plurality of image data Dp0. The processing operation includes a first operation. In the first operation, first display data Dd1 is generated to display an output image 50i including a plurality of symbols 58. One of the plurality of symbols 58 corresponds to one of a plurality of feature values Fv0. One of the plurality of feature values Fv0 corresponds to one of the plurality of image data Dp0. The plurality of symbols 58 are displayed in a first display format DF1 according to the plurality of correspondence information Ic0 corresponding to the plurality of image data Dp0. A design support program capable of providing efficient support is provided.

### Fourth Embodiment

The fourth embodiment relates to a design support method.

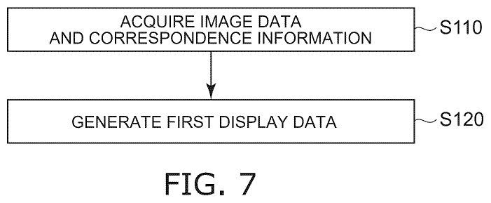

FIG. 7 is a flowchart illustrating a design support method according to the fourth embodiment.

As shown in FIG. 7, a design support method according to the embodiment includes acquiring a plurality of image data Dp0 related to a target device and a plurality of correspondence information Ic0 (step S110). One of the plurality of correspondence information Ic0 corresponds to one of the plurality of image data Dp0. One of the plurality of correspondence information Ic0 includes a design value Vd0 related to one of the plurality of image data Dp0, a score Vs0 related to one of the plurality of image data Dp0, and a characteristic value Vf0 related to one of the plurality of image data Dp0.

The design support method according to the embodiment includes, in a first operation, generating first display data Dd1 that displays an output image 50i including a plurality of symbols 58 (step S120). One of the plurality of symbols 58 corresponds to one of the plurality of feature values Fv0. One of the plurality of feature values Fv0 corresponds to one of the plurality of image data Dp0. The plurality of symbols 58 are displayed in a first display format DF1 according to the plurality of correspondence information Ic0 that correspond to the plurality of image data Dp0. A design support method that can provide efficient support is provided.

According to the embodiment, a design support device, a design support system, a design support program, and a design support method that can provide efficient support are provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the design support devices such processing circuits, interfaces, data generator, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all design support devices, all design support systems, all design support programs, and all design support methods practicable by an appropriate design modification by one skilled in the art based on the design support devices, the design support systems, the design support programs, and the design support methods described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A design support device, comprising:
an interface configured to acquire a plurality of image data related to a target device, and a plurality of correspondence information, one of the plurality of correspondence information corresponding to one of the plurality of image data, the one of the plurality of correspondence information includes a design value related to the one of the plurality of image data, a score related to the one of the plurality of image data, and a characteristic value related to the one of the plurality of image data;
a processing circuit including a data generator configured to perform a first operation, in the first operation, the data generator being configured to generate first display data for displaying an output image including a plurality of symbols, one of the plurality of symbols corresponding to one of a plurality of feature values, one of the plurality of feature values corresponding to the one of the plurality of image data, the plurality of symbols being displayed in a first display format according to the plurality of correspondence information corresponding to the plurality of image data.

2. The design support device according to claim 1, wherein
the plurality of symbols are at positions in a display space according to the plurality of feature values.

3. The design support device according to claim 2, wherein
the plurality of image data include first image data, second image data, and third image data,
the first image data has a first characteristic value,
the second image data has a second characteristic value,
the third image data has a third characteristic value,
the plurality of symbols include a first symbol corresponding to the first characteristic value, a second symbol corresponding to the second characteristic value, and a third symbol corresponding to the third characteristic value;
in a case where a first absolute value of a first difference between the first feature value and the second feature value is smaller than a second absolute value of a second difference between the first feature value and the third feature value, a first distance between a first display position of the first symbol in the display space and a second display position of the second symbol in the display space is shorter than a second distance between the first display position and a third display position of the third symbol in the display space.

4. The design support device according to claim 2, wherein the display space is two-dimensional.

5. The design support device according to claim 1, wherein
the first display format includes a display format based on at least one of colors of the plurality of symbols according to the plurality of correspondence information, brightness of the plurality of symbols according to the plurality of correspondence information, size of the plurality of symbols according to the plurality of correspondence information, or a temporal change of the plurality of symbols according to the plurality of correspondence information.

6. The design support device according to claim 1, wherein
the data generator is configured to further perform an image display operation, and
in the image display operation, the data generator is configured to display at least one of the plurality of image data together with at least a part of the plurality of symbols.

7. The design support device according to claim 1, wherein
the output image includes a cluster display according to a plurality of clusters obtained by classifying the plurality of image data based on the plurality of feature values.

8. The design support device according to claim 1, wherein
at least a part of the first display format corresponds to the plurality of clusters.

9. The design support device according to claim 1, wherein
the data generator is further configured to perform a second operation,
in the second operation, the data generator is configured to generate second display data for displaying the output image including the plurality of symbols;
one of the plurality of symbols corresponds to one of a plurality of feature values, and one of the plurality of feature values corresponds to one of the plurality of image data, and
in the second operation, the plurality of symbols are displayed in a second display format corresponding to a plurality of clusters obtained by classifying the plurality of image data based on the plurality of feature values.

10. The design support device according to claim 1, wherein
the target device includes at least one selected from the group consisting of semiconductor devices, magnetic devices, MEMS devices, sensor devices, imaging devices, light emitting devices, antenna devices, communication devices, computing devices, storage devices, lighting devices, motors, generators, electrical devices, manufacturing devices, mechanical devices, robots, automobiles, aircraft, drones, ships, or tools.

11. The design support device according to claim 1, wherein
the data generator includes a feature extractor,
the feature extractor is configured to extract the plurality of feature values from the plurality of image data,
a dimension of the plurality of feature values is lower than a dimension of the plurality of image data.

12. The design support device according to claim 1, wherein
the data generator includes an image classifier, and
the image classifier is configured to classify the plurality of image data based on the plurality of feature values.

13. The design support device according to claim 1, wherein
the data generator is configured to select at least one of the plurality of image data that is not subject to the output image based on the plurality of correspondence information corresponding to each of the plurality of image data.

14. The design support device according to claim 1, wherein
the processing circuit further includes an optimizer, and
the optimizer is configured to derive the plurality of image data and the plurality of correspondence information.

15. The design support device according to claim 1, wherein
the output image includes a two-dimensional scatter plot of the plurality of symbols.

16. The design support device according to claim 1, wherein
the data generator is configured to perform dimensionality reduction of the plurality of feature values, and
the dimensionality reduction includes performing at least one of t-SNE (t-Distributed Stochastic Neighbor Embedding), PCA (Principal component analysis), or MDS (Multi-dimensional scaling).

17. A design support program to cause a computer to perform a processing operation, the processing operation comprising:
acquiring a plurality of image data related to a target device and a plurality of correspondence information, one of the plurality of correspondence information corresponding to one of the plurality of image data, the one of the plurality of correspondence information including a design value related to the one of the plurality of image data, a score related to the one of the plurality of image data, and a characteristic value related to the one of the plurality of image data; and
performing a first operation, the first operation including generating a first display data for display an output image including a plurality of symbols, one of the plurality of symbols corresponding to one of a plurality of feature values, one of the plurality of feature values corresponding to the one of the plurality of image data, the plurality of symbols being displayed in a first display format according to the plurality of correspondence information corresponding to the plurality of image data.

18. A design support method, comprising:
acquiring a plurality of image data related to a target device and a plurality of correspondence information, one of the plurality of correspondence information corresponding to one of the plurality of image data, the one of the plurality of correspondence information including a design value related to the one of the plurality of image data, a score related to the one of the plurality of image data, and a characteristic value related to the one of the plurality of image data; and
performing a first operation, the first operation including generating a first display data for display an output image including a plurality of symbols, one of the plurality of symbols corresponding to one of a plurality of feature values, one of the plurality of feature values corresponding to the one of the plurality of image data, the plurality of symbols being displayed in a first display format according to the plurality of correspondence information corresponding to the plurality of image data.
